(19) United States
(12) Patent Application Publication
(10) Pub. No.: US 2008/0079478 A1
(43) Pub. Date: Apr. 3, 2008

(54) Controller, information processing apparatus, and communication control method

(75) Inventor: Hiroaki Komaki, Tachikawa-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/902,858

(22) Filed: Sep. 26, 2007

(30) Foreign Application Priority Data
Sep. 28, 2006 (JP) 2006-265786

(51) Int. Cl. H01L 37/00

(52) U.S. Cl. 327/512

(57) ABSTRACT

According to one embodiment, a controller which issues an instruction to initialize a first channel circuit provided in a first semiconductor module and a second channel circuit provided in a second semiconductor module, for communicating with the first channel circuit to the first semiconductor module and the second semiconductor module, includes a temperature acquisition section which acquires a temperature value of the first semiconductor module, and an initialization control section which determines whether or not the acquired temperature value is equal to or higher than a preset temperature value, and issuing an initialization instruction to the first semiconductor module and the second semiconductor module, when determines that the acquired temperature value is equal to or higher than the preset temperature value.

### CROSS-REFERENCE TO RELATED APPLICATIONS

This application is based upon and claims the benefit of priority from Japanese Patent Application No. 2006-265786, filed Sep. 28, 2006, the entire contents of which are incorporated herein by reference.

### BACKGROUND

1. Field

One embodiment of the invention relates to a controller for issuing an instruction to initialize to a channel circuit provided in a semiconductor module, for performing communication, an information processing apparatus provided with the controller, and a communication control method.

2. Description of the Related Art

In the modern society, a semiconductor module is mounted on every instrument and equipment, and is absolutely necessary. The semiconductor module has an operation guaranty temperature and does not operate normally at a temperature other than the operation guaranty temperature.

A technique is disclosed in Jpn. Pat. Appln. KOKAI Publication No. 4-15732, in which when a temperature of a semiconductor module is lower than the lower limit of the operation guaranty temperature range, a reset signal is continuously output to the semiconductor module so as to stop the operation of the semiconductor module, and when the surface temperature is raised by self-heating and reaches the operable temperature range, the rest signal is canceled so as to resume the operation of the semiconductor module.

Now, many of the semiconductor modules are provided with a channel circuit for communicating with other semiconductor modules. The operation guaranty temperature of the channel circuit is pursuant to the operation guaranty temperature of the semiconductor module.

However, when the temperature variation range in which the operation of the channel circuit is guaranteed is narrower than the operation guaranty temperature range (from the upper limit to the lower limit) of the semiconductor module, there occurs a case where although the channel circuit performs communication normally, if the temperature of the semiconductor module varies to exceed the temperature variation range in which the operation of the channel circuit is guaranteed, the channel circuit cannot normally perform communication even in the operation guaranty temperature range of the semiconductor module.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary block diagram showing the schematic configuration of an information processing apparatus according to an embodiment of the present invention; and

FIG. 2 is an exemplary flowchart showing procedures of the initialization processing of the information processing apparatus shown in FIG. 1.

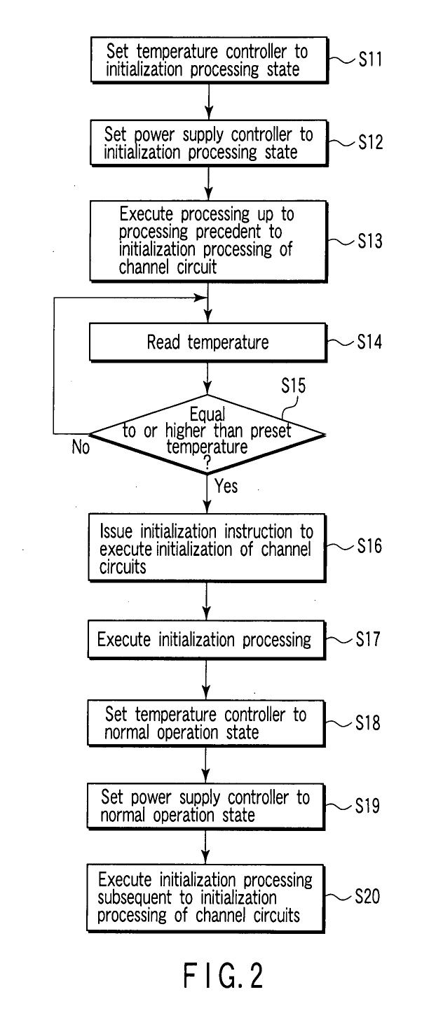

### DETAILED DESCRIPTION

Various embodiments according to the invention will be described hereinafter with reference to the accompanying drawings. In general, according to one embodiment of the invention, a controller which issues an instruction to initialize a first channel circuit provided in a first semiconductor module and a second channel circuit provided in a second semiconductor module, for communicating with the first channel circuit to the first semiconductor module and the second semiconductor module, comprises a temperature acquisition section which acquires a temperature value of the first semiconductor module, and an initialization control section which determines whether or not the acquired temperature value is equal to or higher than a preset temperature value, and issuing an initialization instruction to the first semiconductor module and the second semiconductor module, when determines that the acquired temperature value is equal to or higher than the preset temperature value.

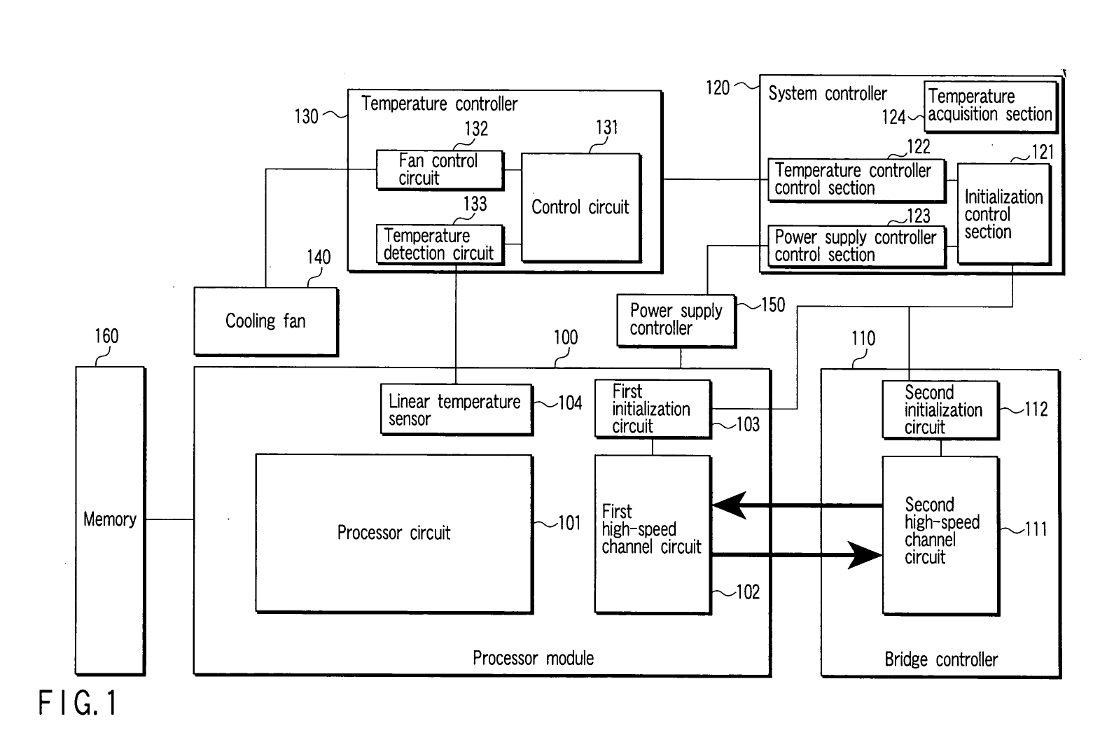

FIG. 1 is a block diagram showing an example of a system configuration of an information processing apparatus according to an embodiment of the present invention.

The information processing apparatus comprises, as shown in FIG. 1, a processor module 100 serving as a first semiconductor module, a bridge controller 110 serving as a second semiconductor module, a system controller 120, a temperature controller 130, a cooling fan 140, a power supply controller 150, a main memory 160, and the like.

The processor module 100 includes a processor circuit 101, a first high-speed channel circuit 102 serving as a first high-speed channel circuit 102, a first initialization circuit 103, and a linear temperature sensor 104. The operation guaranty temperature of the processor module 100 is 5 to 85° C. and the temperature variation range thereof is ΔT_l=80° C. Further, the temperature range in which the first high-speed channel circuit 102 operates is 5 to 85° C. However, the temperature variation range in which the AC characteristic of the I/O section of the first high-speed channel circuit 102 is guaranteed is ΔT_c=55° C.

The processor circuit 101 is a processor provided so as to control the operation of the computer, and executes an OS, application program, and the like loaded from an external storage into the main memory 160.

The first high-speed channel circuit 102 is a circuit for communicating with a second high-speed channel circuit 111 of the bridge controller 110. The first initialization circuit 103 is a circuit for executing initialization (calibration) of the first high-speed channel circuit.

The linear temperature sensor 104 is a sensor of high accuracy (about ±1 to 2° C.) for monitoring the average temperature of a die. The linear temperature sensor 104 is constituted of a single analog (diode) cell, and the average temperature of a silicon die of the processor module 100 is read by a temperature controller 130 provided externally.

The bridge controller 110 to be connected to the processor module 100 includes a video output circuit for outputting image data calculated by the processor module 100 to a display device, an audio input/output circuit, a digital video input/output interface, an IEEE 1394 controller, a network controller, a PCI controller, a PCI express controller, a USB controller, an ATA controller, and the like. Further, the bridge controller 110 includes the second high-speed channel circuit 111 serving as a second high-speed channel circuit 111 for communicating with the high-speed channel circuit of the processor module 100, and a second initialization circuit 112 for initializing the second high-speed channel circuit 111. The first high-speed channel circuit 102 and the second high-speed channel circuit 111 communicate with each other by 8-bit parallel communication. The communication speed is 5 Gbps.

The system controller 120 includes an initialization control section 121, a temperature controller control section (temperature Ctl control section) 122, a power supply controller control section (power Ctl control section) 123, and a temperature acquisition section 124. The system controller 120 has a function of performing starting/abnormality monitoring of the processor module 100 and the bridge controller 110.

The initialization control section 121 has a function of performing initialization of the entire system. The temperature controller control section (temperature Ctl control section) 122 performs setting/control for the temperature controller 130. Further, the power supply controller control section (power supply Ctl control section) 123 performs setting/control for the power supply controller 150. The temperature acquisition section 124 has a function of acquiring a temperature value read from the linear temperature sensor 104 by a temperature detection circuit 133 of the temperature controller 130.

First, initialization of the channel circuits 102 and 111 will be described below. A predetermined data signal is transmitted from the second high-speed channel circuit 111 to the first high-speed channel circuit 102. The first high-speed channel circuit 102 sweeps a sample point for receiving the data signal transmitted from the second high-speed channel circuit 111. When the sample point is swept, two cases, i.e., a case where the data signal can be received and a case where the data signal cannot be received are caused. Further, the first high-speed channel circuit 102 performs setting of the first high-speed channel circuit 102 so that data can be optimally received from a sample point at which the data signal could have been received. For example, the first high-speed channel circuit 102 is set in accordance with a central sample point of the sample point at which the data signal could have been received. After the setting of the first high-speed channel circuit 102 is finished, setting of the second high-speed channel circuit 111 is performed. Incidentally, this initialization technique is a technique of Rambus.

The temperature controller 130 includes a control circuit 131, the temperature detection circuit 133, and a fan control circuit 132. The temperature detection circuit 133 reads a die temperature value of the processor module 100 measured by the linear temperature sensor 104. Further, the fan control circuit 132 controls the rotational speed of the cooling fan 140 for cooling the processor module 100. The control circuit 131 controls the fan control circuit 132 in such a manner that the die temperature is kept in a temperature range designated by the temperature controller control section (temperature Ctl control section) 122 in accordance with the temperature read by the temperature detection circuit 133.

Now, the operation guaranty temperature range of the processor module 100 is ΔT_l=80° C., and the temperature variation range in which the AC characteristic of the I/O section of the first high-speed channel circuit 102 is guaranteed is ΔT_c=55° C. Accordingly, the temperature variation range of the first high-speed channel circuit 102 is narrower than the operation temperature range of the processor circuit 101. Because of the difference in the temperature range, when the temperature of the processor module 100 becomes higher than the temperature of the first high-speed channel circuit 102 at the time of initialization, the first high-speed channel circuit 102 becomes impossible to perform communication normally.

A method by which communication can be normally performed at the first high-speed channel circuit 102 even when the temperature of the processor module 100 rises will be described below.

First, when the user executes a power-on operation, the initialization control section of the system controller 120 starts to operate. First, the temperature controller control section (temperature Ctl control section) 122 sets the temperature controller (temperature Ctl) 130 to the initialization processing state (step S11). By setting the temperature controller to the initialization processing state, the temperature controller 130 sets the rotation of the cooling fan 140 to the stopped state. By causing the cooling fan 140 not to rotate, the processor module 100 is not cooled, and temperature rise of the processor module 100 can be promoted.

Further, the power supply controller (power supply ctl) control section 123 sets the power supply controller (power supply ctl) 150 to the initialization processing state, and enable an output of the drive power (step S12). By setting the power supply controller to the initialization processing state, and enabling the output of the drive power, the power supply controller (power ctl) 150 starts to supply drive power to the processor module 100. In the setting of the initialization processing state, it is desirable that the voltage value of the drive power be the maximum voltage value of the operation voltage range of the processor module 100. By imparting the maximum voltage value to the processor module 100, the self-heating of the processor module 100 is maximized.

Subsequently, the initialization control section 121 executes the processing up to the processing precedent to the initialization processing of the high-speed channel circuits 102 and 111 (step S13).

Further, the temperature acquisition section 124 acquires the value of the temperature of the processor module 100 measured by the linear temperature sensor 104 and read by the temperature controller 130 from the temperature controller 130 (step S14).

Furthermore, the initialization control section 121 determines whether or not the temperature the value of which is acquired by the temperature acquisition section 124 becomes equal to or higher than a preset temperature (step S15). It is desirable that the preset temperature be, for example, a difference between the upper limit of the operation guaranty temperature of the processor module 100 and the temperature variation range in which the AC characteristic of the first high-speed channel circuit 102 is guaranteed. In the case of this embodiment, the upper limit of the operation guaranty temperature is 85° C. and the temperature variation range in which the AC characteristic is guaranteed is 55° C., and hence the preset temperature is 30° C.

The initialization control section 121 periodically acquires the temperature value of the processor module 100 and performs the determination processing of step S15 until the temperature becomes equal to or higher than the preset temperature. When the temperature becomes equal to or higher than the preset temperature (Yes in step S15), the initialization control section 121 issues an initialization instruction to execute the initialization processing of the first high-speed channel circuit 102 and the second high-speed channel circuit 111 to the processor module 100 and the bridge controller 110 (step S16). The first initialization circuit 103 of the processor module 100 and the second initialization circuit 112 of the bridge controller 110 execute the above-mentioned initialization processing (step S17).

After the initialization is finished, the temperature controller control section (temperature Ctl control section) 122 sets the setting of the temperature controller (temperature Ctl) 130 again to the normal system operation state on the basis of the instruction from the initialization control section 121 (step S18). By the resetting, the rotation of the cooling fan 140 is enabled, and the temperature controller 130 controls the rotation of the cooling fan 140 such that the temperature of the processor module 100 becomes equal to or lower than the upper limit of the operation temperature.

After the initialization is finished, the power supply controller control section (power supply ctl control section) 113 sets the power supply controller (power supply ctl) 150 again to the normal system operation state on the basis of the instruction from the initialization control section 121 (step S19).

Subsequently, the initialization control section 121 executes the initialization processing subsequent to the initialization processing of the high-speed channel circuits (step S20). When the initialization processing is finished, an OS and an application program are loaded into the main memory 160 from the external storage, and are executed by the processor circuit 101.

According to this embodiment, by executing the initialization processing of the first high-speed channel circuit after the temperature of the processor module 100 becomes 30° C., communication between the processor module 100 and the bridge controller 110 can be performed normally even when the temperature of the processor module 100 becomes the upper limit of the operation guaranty temperature. For example, a case is assumed where the initialization processing of the first high-speed channel circuit is executed in a state in which the temperature of the processor module 100 is 20° C. In this case, since the temperature variation range in which the AC characteristic of the first high-speed channel circuit 102 is guaranteed is 55° C., the upper limit of the temperature at which the first high-speed channel circuit 102 can normally perform communication is 75° C. Accordingly, when the temperature of the processor module 100 becomes the upper limit (85° C.) of the operation guaranty temperature, the first high-speed channel circuit 102 becomes unable to perform communication normally. However, when the initialization processing of the first high-speed channel circuit is executed after the temperature of the processor module 100 becomes 30° C., the upper limit of the temperature at which the first high-speed channel circuit 102 can normally perform communication becomes 85° C. Therefore, the first high-speed channel circuit 102 can perform communication normally even when the temperature of the processor module 100 becomes the upper limit (85° C.) of the operation guaranty temperature.

Incidentally, in the case of this embodiment, initialization processing of the first high-speed channel circuit 102 is executed after the temperature of the processor module 100 becomes 30° C., and thus there is the possibility of the start-up time of the system becoming long. When first priority is given to the start-up time, it is advisable to supply the processor module 100 with power at all times. Further, it is also advisable to provide the processor module 100 with a heater, and heat the processor module by means of the heater. Furthermore, it is also advisable to cause the processor circuit 101 to execute a program that can be processed only within the processor circuit 101 when the user performs a power-on operation, and promote a temperature rise thereof.

When the processor module 100 is supplied with power at all times or the processor module 100 is heated by a heater, a drawback is caused that the standby power consumption is increased in compensation for the advantage that a period from the power-on operation performed by the user to the start-up of execution of software can be shortened. Thus, in a system in which it can be permitted that a period in which the high-speed channel cannot be used is temporarily exist after execution of software is started, the processor module 100 is once started with the initial temperature of the system left as it is in order to shorten the apparent start-up time, and when the silicon temperature exceeds 30° C. after the start of the execution of the software, initialization processing of the high-speed channel is executed again, whereby it is possible to prevent the silicon temperature rise waiting time from becoming long and avoid an increase in the standby power consumption.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A controller which issues an instruction to initialize a first channel circuit provided in a first semiconductor module and a second channel circuit provided in a second semiconductor module, for communicating with the first channel circuit to the first semiconductor module and the second semiconductor module, comprising:
a temperature acquisition section which acquires a temperature value of the first semiconductor module; and
an initialization control section which determines whether or not the acquired temperature value is equal to or higher than a preset temperature value, and issuing an initialization instruction to the first semiconductor module and the second semiconductor module, when determines that the acquired temperature value is equal to or higher than the preset temperature value.

2. The controller according to claim 1, wherein an upper limit of an operation temperature range of the first semiconductor module is Tu,
a temperature variation range in which a communication characteristic of the first channel circuit is guaranteed is ΔT, and
the preset temperature is ΔT−Tu.

3. The controller according to claim 1, further comprising an instructing section which instructs a power supply controller to supply the maximum voltage of an operation voltage range of the first semiconductor module to the first semiconductor module, when it is determined by the initialization control section that the acquired temperature value is not equal to or higher than the preset temperature value.

4. The controller according to claim 1, further comprising a cooling stopping section which stops an operation of the cooling device, when it is determined by the initialization control section that the acquired temperature value is not equal to or higher than the preset temperature value.

5. The controller according to claim 1, further comprising a drive power supply section which causes a power supply controller to supply the drive power to the first semiconductor module when a user does not perform a power-on operation.

6. The controller according to claim 1, wherein the initialization control section issues the initialization instruction to the first semiconductor module and the second semiconductor module when a user performs a power-on operation, determines, after the initialization instruction is issued when the power is turned on, whether or not the acquired temperature value is equal to or higher than a preset temperature value and, when determines that the acquired temperature value is equal to or higher than the preset temperature value, issues the initialization instruction.

7. An information processing apparatus comprising:
a first semiconductor module including a first channel circuit;
a second semiconductor module including a second channel circuit for communicating with the first channel circuit;
a temperature acquisition section which acquires a temperature value of the first semiconductor module;
a temperature judgment section which determines whether or not the acquired temperature value is equal to or higher than a preset temperature value; and
an initialization control section which issues an initialization instruction to execute initialization of communication between the first channel circuit and the second channel circuit to the first semiconductor module and the second semiconductor module, when it is determined that the acquired temperature value is equal to or higher than the preset temperature value.

8. The information processing apparatus according to claim 7, wherein an upper limit of an operation temperature range of the first semiconductor module is Tu,
a temperature variation range in which a communication characteristic of the first channel circuit is guaranteed is ΔT, and
the preset temperature value is ΔT−Tu.

9. The information processing apparatus according to claim 7, further comprising a instructing section which instructs a power supply controller to supply the maximum voltage of an operation voltage range of the first semiconductor module to the first semiconductor module, when it is determined by the initialization control section that the acquired temperature value is not equal to or higher than the preset temperature value.

10. The information processing apparatus according to claim 7, further comprising:
a cooling device for cooling the first semiconductor module; and
a cooling stopping section which stops an operation of the cooling device, when it is determined by the initialization control section that the acquired temperature value is not equal to or higher than the preset temperature value.

11. The information processing apparatus according to claim 7, further comprising a power supply controller for supplying drive power to the first semiconductor module, wherein
the controller further includes instructing section which causes the power supply controller to supply the drive power to the first semiconductor module when a user does not perform a power-on operation.

12. The information processing apparatus according to claim 7, wherein the initialization control section issues the initialization instruction to the first semiconductor module and the second semiconductor module when a user performs a power-on operation,
the temperature judgment section determines whether or not the acquired temperature value is equal to or higher than a preset temperature value, after the initialization instruction is issued when the power is turned on and,
the initialization control section issues the initialization instruction, when determines that the acquired temperature value is equal to or higher than the preset temperature value.

13. The information processing apparatus according to claim 7, further comprising a heating device which heats the first semiconductor module when the first semiconductor module is in a nonoperating state.

14. A communication control method comprising:
acquiring a temperature value of a first semiconductor module including a first channel circuit;
determining whether or not the acquired temperature value is equal to or higher than a preset temperature value; and
issuing an initialization instruction to execute initialization of communication between the first channel circuit and a second channel circuit for communicating with the first channel circuit to the first semiconductor module and a second semiconductor module including the second channel circuit, when it is determined that the acquired temperature value is equal to or higher than the preset temperature value.

15. The communication control method according to claim 14, wherein an upper limit of an operation temperature range of the first semiconductor module is Tu,
a temperature variation range in which a communication characteristic of the first channel circuit is guaranteed is ΔT, and
the preset temperature value is ΔT−Tu.

16. The communication control method according to claim 14, further comprising instructing a power supply controller to supply the maximum voltage of an operation voltage range of the first semiconductor module to the first semiconductor module, when it is determined that the acquired temperature value is not equal to or higher than the preset temperature value.
